(19) United States
(12) Patent Application Publication
(10) Pub. No.: US 2008/0241354 A1
(43) Pub. Date: Oct. 2, 2008

(54) APPARATUS AND METHODS FOR CURING A LAYER BY MONITORING GAS SPECIES EVOLVED DURING BAKING

(75) Inventor: Thomas E. Winter, Pleasant Valley, NY (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TOKYO ELECTRON LIMITED, Tokyo (JP)

(21) Appl. No.: 11/692,669

(22) Filed: Mar. 28, 2007

(51) Int. Cl. C23C 16/52

(52) U.S. Cl. 427/8; 118/699

(57) ABSTRACT

A heat treatment apparatus and method for curing a layer of a processable material on a substrate. The apparatus includes a residual gas analyzer that communicates with a process space in which the layer is heated to cure the processable material. A controller, which is electrically connected to the residual gas analyzer, is operable to adjust a bake time for the layer in relation to a concentration of a gas species evolved from the processable material.

### FIELD OF THE INVENTION

The invention is related to semiconductor processing, in particular, to apparatus and methods for curing a layer of a processable material on a substrate.

### BACKGROUND OF THE INVENTION

Lithographic processes are widely used in the manufacture of semiconductor devices and other patterned structures. In track photolithographic processing used in the fabrication of semiconductor devices, the following sorts of processes may be performed in sequence: resist coating that coats a resist solution on a semiconductor wafer to form a resist film, exposure processing to expose a predetermined pattern on the resist film, heat processing to promote a chemical reaction within the resist film after exposure, developing processing to develop the exposed resist film, etc.

The baking (curing) of organic films is critical to the manufacturing process used for integrated circuits. This process is typically referred to as a “post apply bake” or PAB. Typical films include top coat barrier layers (TC), top coat antireflective layers (TARC), bottom antireflective layers (BARC), imaging layers (PR or photoresist), and sacrificial and barrier layers (hard mask) for etch stopping.

The bake process time and temperature are used to drive out solvents and cure or harden the film and thereby define the characteristics of the film at exposure and post exposure develop where circuit features are defined, prior to etching the features into the substrate. The amount of solvent remaining in this film can influence the lithographic and etch properties. Current technology controls the curing process with a time and temperature relationship, then relies on measuring the film thickness, which is a direct interpretation of the film's optical properties, to verify if the bake process was successful. If the post bake film properties are not identical wafer to wafer, critical dimension may vary as well for the same reasons the film thickness varies: the optical properties of the imaging layer are not consistent.

Current bake systems monitor bake temperature and process start and stop times to insure proper processing. The post bake film characteristics can be somewhat verified with film thickness or other additional testing. However, this testing may no longer be accurate enough to confirm if the desired film characteristics have been achieved as these systems average the film properties through the bulk material. Also the addition of other stops to the manufacturing process is not desirable for throughput and added defect concerns.

What is needed therefore in the art is a real time, in-situ method to ensure the bake process time versus temperature relationship is repeatable and will be more accurate leading to desirable results.

### SUMMARY OF THE INVENTION

In one embodiment, a heat treatment apparatus is provided for heating a substrate, such as a semiconducting wafer. The heat treatment apparatus comprises an enclosure defining a process space, a substrate support configured to support the substrate in the process space, and a heating element configured to heat the substrate. A residual gas analyzer communicates with the process space. The residual gas analyzer samples an atmosphere inside the process space and generates signals relating to a concentration of at least one gaseous species in the atmosphere. A controller is electrically connected to the residual gas analyzer and is also electrically connected with the heating element. The controller is operable to adjust an amount of time that the heating element transfers heat energy to the substrate in response to the signals communicated from the residual gas analyzer.

In another embodiment, a method is provided for curing a layer of a processable material on a substrate. The method comprises baking the layer of material inside a process chamber to generate a gaseous product evolved from the processable material in the layer and measuring a concentration of the gaseous product inside the process chamber as a function of bake time. The method further comprises adjusting a length of the bake time in response to the measured concentration of the gaseous product.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the principles of the invention.

FIG. 1 is a plan view showing the general structure of a coating/developing system used to process substrates in accordance with an embodiment of the invention.

FIG. 2 is a front view of the coating/developing system in FIG. 1.

FIG. 3 is a rear view of the coating/developing system in FIG. 1.

FIG. 4 is a perspective plan view of a single heat treatment apparatus of FIG. 1.

FIG. 5 is a cross-sectional view of the heat treatment apparatus of FIG. 4.

FIG. 6 is a graph showing an exemplary trace of gas concentration as a function of bake time.

FIG. 7 is a flow diagram depicting a process for determining an acceptable trace.

FIG. 8 is a flow diagram depicting an exemplary process for curing a layer on a substrate.

FIG. 9 is a graph showing sample traces of gas concentration as a function of bake time.

### DETAILED DESCRIPTION

The invention monitors a curing process of a thin film in real time by monitoring a concentration of evolved gases versus time, in-situ. Traditional methods of monitoring film curing in-situ rely on using the parameters of temperature and time, meaning heater zones on a bake plate are monitored for temperature versus process time only. The current state of the art monitors the process inputs or the catalyst for the reaction. The invention described herein will monitor the results or outputs of the reaction in a post apply bake process. This is an improved method to control the chemical composition of post-baked thin films on substrates, such as semiconducting wafers. The method provides a more accurate representation of the film quality after bake than the traditional methods. This invention may be used as part of the processing of a substrate on a coating/developing system and does not require any additional steps to the process or any extra handling of the substrate.

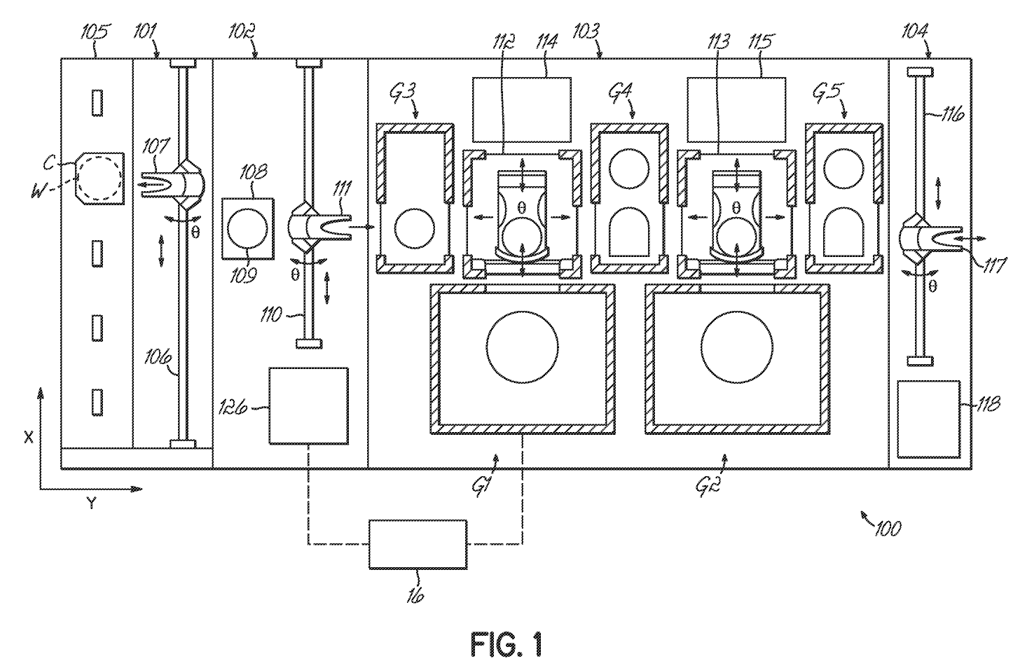

An exemplary coating/developing system 100, as shown in FIG. 1, may be constituted to integrally connect a cassette station 101, which transports a cassette typically holding 25 wafers W, for example, into the coating/developing system 100 from outside and which transports a wafer W to the cassette C; an inspection station 102 which performs a predetermined inspection on the wafer W; a processing station 103 with a plurality of types of processing devices disposed in stages to perform predetermined processes in a layered manner in the photolithography step; and an interface unit 104, provided adjacent to the processing station 103, for delivering the wafer W to an exposure device (not shown).

A cassette support stand 105 is provided at the cassette station 101; the cassette support stand 105 may freely carry a plurality of cassettes C in a row in the X direction (vertically, in FIG. 1). The cassette station 101 is provided with a wafer transporter 107 able to move on the transport path 106 in the X direction. The wafer transporter 107 may also move freely in the wafer array direction (Z direction; perpendicular) of the wafers W housed in the cassette C and can selectively access the wafer W vertically arrayed in the cassette C. The wafer transporter 107 may rotate around an axis (θ direction) in the particular direction, and may also access the inspection station's transfer unit 108.

A pattern measuring device 126 may be disposed at the negative X direction side (downward in FIG. 1) of the inspection station 102, for example. Disposed at the cassette station 101 side of inspection station 102 is the transfer unit 108 for transferring the wafer W from the cassette station 101. A carrying unit 109 for carrying the wafer W may be provided in the transfer unit 108. A wafer transporter 111 able to move on a transport path 110 in the X direction may be provided at the positive X direction side (upward in FIG. 1) of the pattern measuring device 126. The wafer transporter 111 also may move vertically and rotate freely in the θ direction, and may also access the transfer unit 108 in each processing device in a third processing device group G3 at the processing station 103 side.

A processing station 103 adjacent to the inspection station 102 is provided with a plurality of processing devices disposed in stages, such as five processing device groups G1-G5. The first processing device group G1 and the second processing device group G2 are disposed in sequence from the inspection station 102 side, at the negative X direction side (downward in FIG. 1) of the processing station 103. The third processing device group G3, fourth processing device group G4, and fifth processing device group G5 are disposed in sequence from the inspection station 102 side, at the positive X direction side (upward in FIG. 1) of the processing station 103. A first transport device 112 is provided between the third processing device group G3 and the fourth processing device group G4. The transport device 112 may transport the wafer W to access each device in the first processing device group G1, third processing device group G3, and fourth processing device group G4. A second transport device 113 transports the wafer W and selectively accesses the second processing device group G2, fourth processing device group G4, and fifth processing device group, G5.

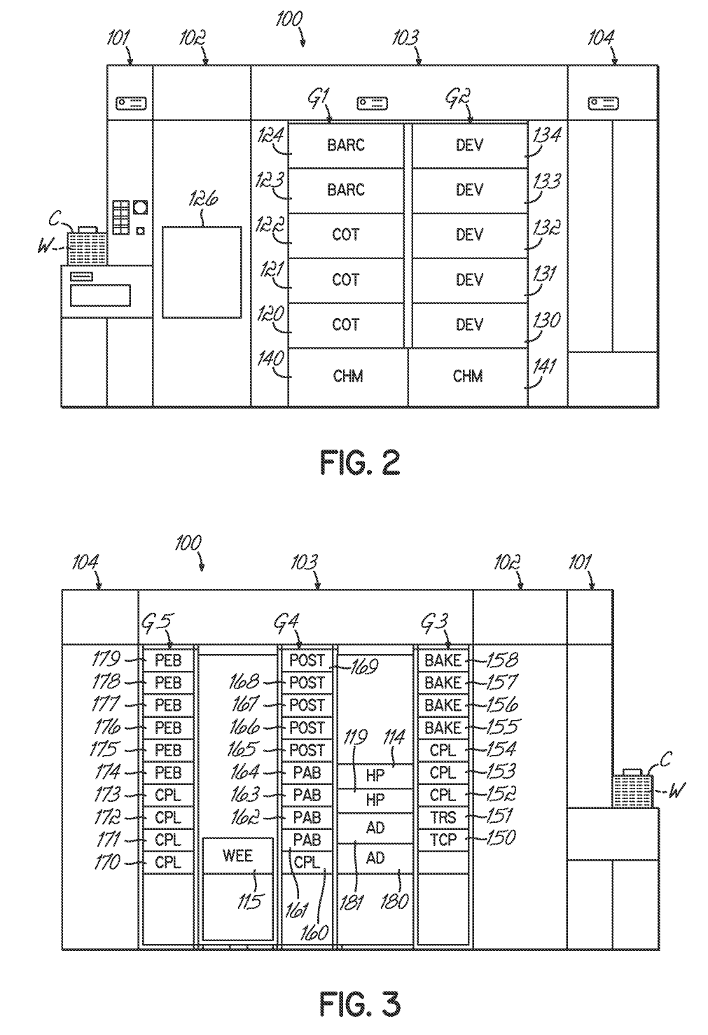

Referring now to FIG. 2, the first processing device group G1 stacks liquid processing devices that supply a predetermined liquid spin on material to the wafer W and process it. Devices such as spin coating devices 120, 121, and 122, which may apply a resist solution to the wafer W and form a resist film, and bottom coating devices 123 and 124, which form an anti-reflection film that prevents light reflection during exposure processing, may be arranged in five levels in sequence from the bottom. The second processing device group G2 stacks liquid processing devices such as developing devices 130-134, which supply developing fluid to the wafer W and develop it, in five levels in sequence from the bottom. Also, terminal chambers 140 and 141 are provided at the lowest stages of the first processing device group G1 and the second processing device group G2 in order to supply processing liquids to the liquid processing devices in the processing device groups G1 and G2.

Also, as shown in FIG. 3, for example, the third processing device group G3 stacks temperature regulation device 150, transition device 151 for transfer of the wafer W, high precision temperature regulation devices 152-154, which regulate the temperature of the wafer W under high precision temperature management, and high temperature heating devices 155-158, which heat the wafer W to high temperature, in nine levels in sequence from the bottom.

The fourth processing device group G4 stacks a high precision temperature regulation device 160, pre-baking devices 161-164 for heating the wafer W after resist coating processing, and post-baking devices 165-169, which heat the wafer W after developing, in ten levels in sequence from the bottom.

The fifth processing device group G5 stacks a plurality of heating devices that heat the wafer W, such as high precision temperature regulation devices 170-173, and post-exposure baking devices 174-179 in ten levels in sequence from the bottom.

A plurality of processing devices may be disposed at the positive X direction side of the first transport device 112 as shown in FIG. 1. Adhesion devices 180 and 181 for making the wafer W hydrophobic and heating devices 119 and 114 for heating the wafer W are stacked in four levels in sequence from the bottom, as shown in FIG. 3, for example. A peripheral exposure device 115 for selectively exposing only the edge of the wafer W may be disposed at the positive X direction side of the second transport device 113 as shown in FIG. 1.

Provided in the interface unit 104 are a wafer transporter 117 that moves on a transport path 116 extending in the X direction as shown in FIG. 1 and a buffer cassette 118. The wafer transporter 117 can move in the Z direction and can rotate in the θ direction; and can transport the wafer W and access the exposure device (not shown) adjacent to the interface unit 104 and the buffer cassette 118 and the fifth processing device group G5.

The percent concentration of solvent and/or out gassing materials will be monitored during the bake process by a controller, which may be a computer running monitoring software in some embodiments. A trace from a residual gas analyzer output versus the processing time will be created during the bake process. Corrective actions to the wafer in process may be triggered by the trace data being created; meaning immediate adjustments to the length of the bake may be dictated by the data as it is generated.

Embodiments of the invention use a residual gas analyzer (quadrupole mass spectrometer or other suitable detector) to monitor a gas exhausted from at least one of the baking units 161-164. Solvent out gassing may be sufficient, however, other materials such as polymer or other chemical compounds may be added to the gas monitoring system if required for special applications. These systems are commercially available.

The controller determines a suitable baseline trace to compare all subsequent wafer processing by running, measuring, and using statistical analysis to generate a typical trace. A user of the coating/developing system 100 may determine and adjust a length of a sample time and when during the bake process that the trace data will be evaluated for likeness to the baseline trace. This may allow for tuning the system for optimum results. The user may also determine bake time corrections for the system to use, which may be stored in a look-up table available to the controller. Bake times may be adjusted up or down based on the data in this table.

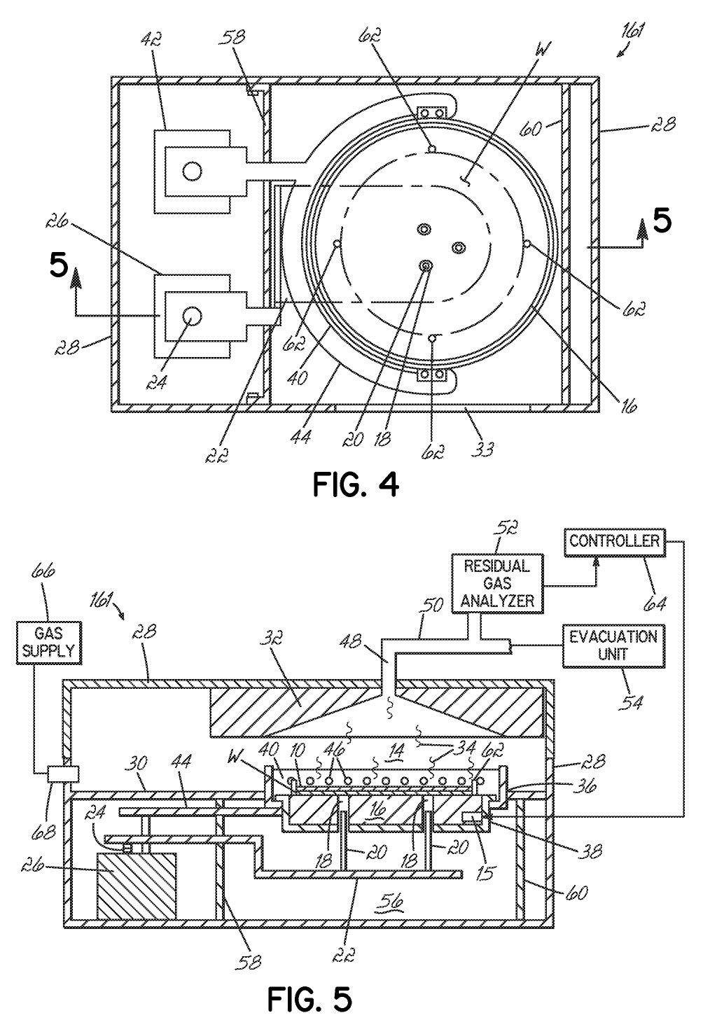

With reference to FIGS. 4 and 5, an exemplary baking unit 161 that may be used for a post apply bake may contain a heat treatment apparatus in which wafers W are heated to temperatures above room temperature. Each heat treatment apparatus includes a process space 14, a substrate support in the representative form of a hotplate 16, and a resistance heater 15 embedded in the hotplate 16.

The hotplate 16 has a plurality of through-holes 18 and a plurality of lift pins 20 inserted into the through-holes 18. The lift pins 20 are connected to and supported by an arm 22, which is further connected to and supported by a rod 24 of a vertical cylinder 26. When the rod 24 is actuated to protrude from the cylinder 26, the lift pins 20 protrude from the hotplate 16, thereby lifting the wafer W.

The process space 14 is defined by a process chamber or enclosure consisting collectively of a wall 28, a horizontal shielding plate 30, and an exhaust cover 32. Opening 33 may be formed at a front surface side or a rear surface side of the process space 14. The wafer W may be loaded into and unloaded from the process space 14 through the opening 33. In some embodiments, the opening 33 may close to seal the baking unit during the processing of the wafer W. A circular opening 36 is formed at the center of the horizontal shielding plate 30. The hotplate 16 is housed in the opening 36. The hotplate 16 is supported by the horizontal shielding plate 30 with the aid of a supporting plate 38.

In some embodiments, a ring-form shutter 40 is attached to the outer periphery of the hotplate 16. Air holes 46 may be formed along the periphery of the shutter 40 at intervals of central angles of approximately two degrees. The air holes 46 communicate with a cooling gas supply source (not shown).

The shutter 40 is liftably supported by a cylinder 42 via a shutter arm 44. The shutter 40 is positioned at a place lower than the hotplate 16 at non-operation time, whereas, at an operation time, shutter 40 may be lifted up to a position higher than the hotplate 16 and between the hotplate 16 and the exhaust cover 32. When the shutter 40 is lifted up, a cooling gas, such as nitrogen gas or air, may be exhausted from the air holes 46.

With continued reference to FIGS. 4 and 5, an exhaust port 48 at the center of the exhaust cover 32 communicates with an exhaust pipe 50. A gaseous product 34 is generated from the layer 10 on wafer W as the hotplate 16 elevates the temperature of the wafer W. The gaseous product 34 may be exhausted through the exhaust port 48 and vented from the process space 14 via exhaust pipe 50 to an evacuation unit 54, which may be a vacuum pump with a suitable pumping capacity matched to the characteristics of the process space 14. A residual gas analyzer 52 communicates with the process space 14.

Residual gas analyzers, such as residual gas analyzer 52, are familiar devices used in vacuum technology for the detection of gas species and their concentrations in a processing chamber. The residual gas analyzer 52 may be any type of mass spectrometer and, in one embodiment, is a quadrupole mass spectrometer. Exemplary residual gas analyzers (“RGA”) suitable for use in a processing chamber environment are commercially available from various sources, such as MKS Instruments (Andover, Mass.).

The residual gas analyzer 52 samples the gases flowing in the exhaust pipe 50 and, in particular, analyzes the gases evolved from layer 10 into the atmosphere inside the process space 14 during the baking process by ionizing a fraction of the gas molecules in each sampled volume, separating the ions by mass, and measuring the quantity of ions at each mass. The residual gas analyzer 52 may rely on a mass sampling technique that monitors only one or more user-selected peaks characteristic of the gases evolving from the layer 10. The magnitude of the ion current as measured by the residual gas analyzer 52 is used to determine the partial pressure of the respective gases originating from the heated processable material in the layer 10.

The amounts and/or ratios (e.g., partial pressures) of various residual gases in the process space 14 change as the baking process proceeds and the volume of evolved gas decreases with increasing baking time. Specifically, the amount of the different gas species in the gaseous product 34 evolving from the layer 10 changes as the layer 10 is heat cured. By monitoring the change in the amounts and/or ratios of the evolved gases from layer 10, the residual gas analyzer 52 may be used to improve process control by employing real time, in situ monitoring to regulate the relationship between process temperature and bake process time. The residual gas analyzer 52 may be used to troubleshoot out of control baking processes or to prevent baking processes from reaching an out of control condition.

The gaseous product 34 may be a single solvent or multiple solvents. It may also contain a mixture of any one or more of solvents, polymers, photo acid generators, base inhibitors, or any other by-products that are generated as a result of thermally processing layer 10. The residual gas analyzer 52 may be tuned for a particular solvent or solvents in the gaseous product 34. The residual gas analyzer 52 may be mounted anywhere along the exhaust line, coupled to exhaust pipe 50. For example, it may be mounted proximate to the exhaust port 48 in the exhaust cover 32 as shown in FIG. 5. The process space 14 provides a closed environment during the baking process. A supply 66 of fresh gas may be introduced in the process space 14 through a gas injector 68 as the gaseous product 34 is removed. An inert gas, such as nitrogen, may be used in some embodiments as the fresh gas introduced by supply 66.

A compartment 56 defined by the shielding plate 30, two sidewalls 58, 60, and the outer wall 28 is formed below the horizontal shielding plate 30. Hotplate supporting plate 38, shutter arm 44, lift pin arm 22, and liftable cylinders 26, 42 may be arranged in the compartment 56.

With reference to FIG. 4, a plurality of projections 62 is formed on an upper surface of the hotplate 16 for accurately positioning the wafer W. In addition, a plurality of smaller projections (not shown) may be formed on the upper surface of the hotplate 16. When the wafer W is mounted on the hotplate 16, top portions of these smaller projections may contact the wafer W, which may produce a small gap between the wafer W and the hotplate 16 that may prevent the lower surface of the wafer W from being strained and damaged.

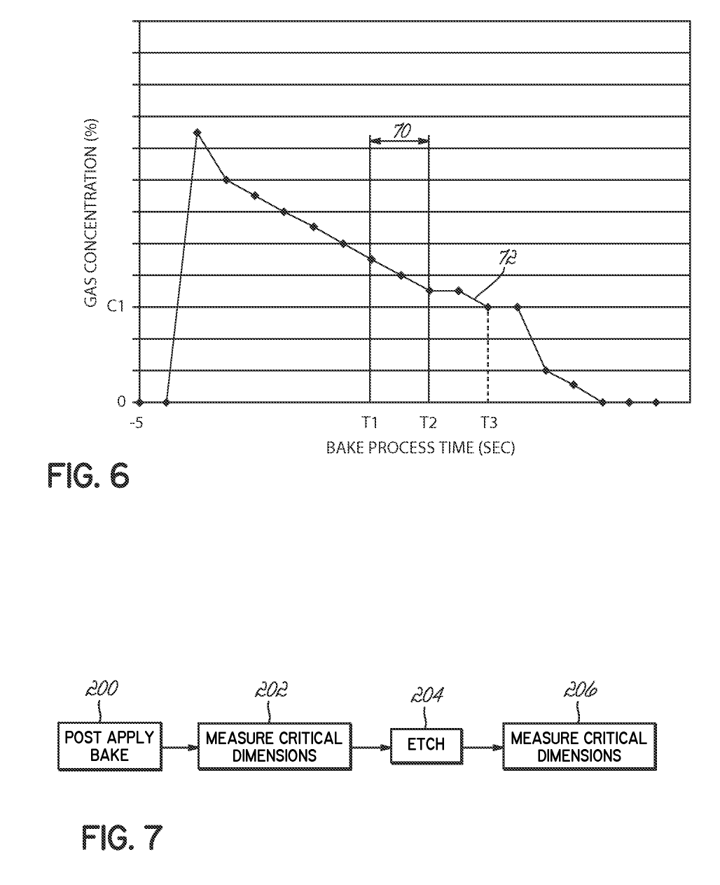

A controller 64 (FIG. 5) is electrically connected to the residual gas analyzer 52 and is electrically connected with the heating element 15. The residual gas analyzer 52 monitors the gaseous product 34, such as a solvent discussed above, by its molecular weight. Other analyzers may be added to monitor other by-products of the application required further detailed analysis. Data from the residual gas analyzer 52 is sent to the controller 64, which monitors and records the gas concentration versus time. This data is referred to as a residual gas trace 72 as can be seen in FIG. 6. In a repeatable process, the percent solvent emitted versus time should be nearly identical wafer to wafer.

The controller 64 may be taught to recognize an acceptable trace by the process shown in FIG. 7. For a set of multiple test wafers W, traditionally 25, a post apply bake is performed in block 200. Critical dimensions are measured in block 202, typically by a metrology unit, which may be inline with the process or located offline. The wafer is sent through an etching process in block 204. Critical dimensions are again measured after the etch in block 206 by a metrology unit, such as the pattern measuring device 126 (FIGS. 1 and 2), which may again be inline with the process or may be located offline. After each of the bakes in block 200, the multiple test wafer trace characteristics are saved in the controller. A baseline trace may then be determined by using curve fitting statistics and averaging repeated data. The multiple test wafer baseline gas trace may then be used as the standard to which all others will be compared. As wafers W are processed, each new trace may be compared to the baseline gas trace by using curve fitting algorithms to calculate goodness of fit and R squared or other suitable statistics.

A feedback system may be created to adjust the bake process time for a representative trace 72 that deviates from the baseline gas trace. The controller 64 is operable to adjust an amount of time that the hotplate 16 transfers heat energy to the wafer W in response to the signals communicated as feedback to the controller 64 from the residual gas analyzer 52. A decision to compensate the bake time or not may be made be based on an average concentration of one or more gas species taken over a sample time 70 between a first time T1 and a second time T2 as best seen on the graph in FIG. 6. A goal may be to achieve a percentage out gassing C1 at a specific time T3. This relationship may be determined as an optimum concentration through customer testing. The optimum concentration occurs at a time such as T3 based on the baseline gas trace data. Gas concentrations are determined as the average during the sample time 70, where the duration of the sample time 70 may be a period of at least about 5 seconds or longer. The average concentration is compared to the baseline. If the concentration is high as compared to the baseline gas trace, the bake time will be extended by the controller 64 to meet the goal. If the concentration is low as compared to the baseline gas trace, the bake time will be reduced by the controller 64 to meet the goal.

An alarm may be included in some embodiments with the ability to alarm and flag wafers W that are not processed identically. A user selectable error value may be inputted to set alarm conditions based on the trace characteristics and processing time. If one trace curve does not fit well when compared to the baseline gas trace, an alarm may be sent to the main user interface for the coating/developing system 100 and the wafer may be identified for special inspection or treatment at the etch step by the controller 64. The controller 64 may issue additional warning alarms for wafers that are within the acceptable range when compared to the baseline gas trace, but may be nearing unacceptable allowable limits.

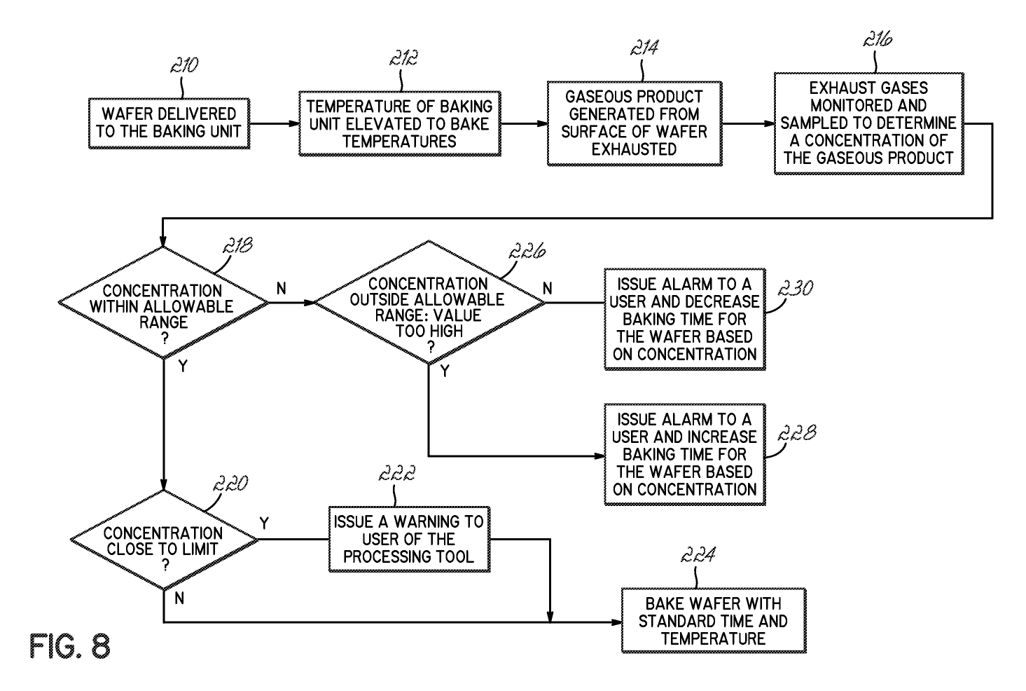

A process for curing a thin film on a substrate, such as a wafer, that is consistent with the invention can be seen in FIG. 8. In block 210, a wafer is delivered to the baking unit. In block 212, the temperature of the baking unit is elevated to a bake temperature. During the bake process, heat energy is transferred from a hotplate in the baking unit to the wafer, which in turn heats the thin film on the wafer. In block 214, a gaseous product is generated or evolved from the thin film on the surface of the wafer. The gaseous product is exhausted from the baking unit. In block 216, the exhaust gasses are monitored and sampled by a residual gas analyzer or some other compatible device capable of determining the concentration of the gaseous product as a function of time.

The concentrations are sent to a controller where the concentrations are analyzed against a baseline. If the controller determines that the concentrations are within the allowable range (YES branch of decision block 218), the controller then determines if the concentrations are close to unacceptable limits. If the concentrations are not close to the limits (NO branch of decision block 220), the wafer is baked for the standard time and at the standard temperature in block 224. If the controller determines that the concentration is near unacceptable limits (YES branch of decision block 220) as an anomaly, a warning is used to a user in block 222 to notify the user of the anomaly and the wafer is baked for the standard time and at the standard temperature in block 224.

If the concentrations are outside of the acceptable range (NO branch of decision block 218) as an anomaly, the controller determines if the values are too high or too low. If the concentration values are too high (YES branch of decision block 226) as the anomaly, an alarm is issued to a user to notify the user of the anomaly and the baking time for the wafer is increased based on the deviation of the concentration from the baseline in block 228. If the concentration values are too low (NO branch of decision block 226) as the anomaly, an alarm is issued to a user to notify the user of the anomaly and the baking time for the wafer is decreased based on the deviation of the concentration from the baseline in block 230. When an alarm is issued, the user may take additional action as discussed above.

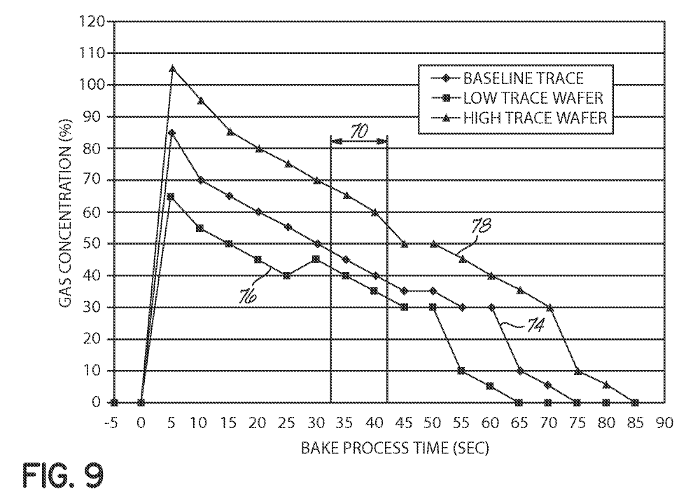

A specific example of traces from two wafers and a baseline may be seen in FIG. 9. The graph shows two traces 76, 78 that deviate from the baseline gas trace 74. A decision to compensate the bake time or not may be made be based on an average concentration taken over a sample time 70 at the 35 to 40 second time as best seen on the graph in FIG. 9. The graph demonstrates the three cases that can occur during a post apply bake. A goal for this example may be to achieve 30 percent out gassing in 57 seconds. The optimum concentration occurs at 57 seconds based on the baseline gas trace 74 data. The sample time 70 in this example is 10 seconds. Gas concentrations for this example are determined as the average during the sample time 70. The average is compared to the baseline. If the concentration is high as compared to the baseline gas trace 74, the bake time will be extended by the controller 64 to meet the goal. For the high gas trace 78, the goal would be achieved at about 71 seconds. If the concentration is low as compared to the baseline gas trace 74, the bake time will be reduced by the controller 64 to meet the 30 percent goal. For the low gas trace 76 in this example, the optimum would be achieved at about 45 seconds.

An alarm included in the embodiment for this example is configured to alarm and flag wafers W that are not processed identically. User selectable error values are inputted to set alarm conditions based on the trace characteristics and processing time. Trace curves 76, 78 would issue an alarm, which would be sent to the main user interface for the coating/developing system 100. The wafers, being out of compliance with the baseline, would be identified for special inspection or treatment at the etch step by the controller 64.

While the invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the spirit or scope of applicant's general inventive concept.

What is claimed is:

1. A heat treatment apparatus for heating a substrate, the heat treatment apparatus comprising:
an enclosure defining a process space;
a substrate support configured to support the substrate in the process space;
a heating element configured to heat the substrate;
a residual gas analyzer communicating with the process space, the residual gas analyzer operative to sample an atmosphere inside the process space and to generate signals relating to a concentration of at least one gaseous species in the atmosphere; and
a controller electrically connected to the residual gas analyzer and electrically connected with the heating element, the controller operable to adjust an amount of time that the heating element transfers heat energy to the substrate in response to the signals communicated from the residual gas analyzer.

2. The heat treatment apparatus of claim 1 further comprising:
an alarm electrically coupled with the controller, the alarm operable to notify a user of an anomaly in the concentration of the at least one gaseous species.

3. The heat treatment apparatus of claim 2 wherein the alarm is further operable to issue a warning to a user when the concentration of the at least one gaseous species approaches an allowable limit.

4. The heat treatment apparatus of claim 2 wherein the alarm is further operable to issue a warning to a user in conjunction with the time adjustment.

5. The heat treatment apparatus of claim 1 further comprising:
an exhaust port in the enclosure, the residual gas analyzer communicating with the process space through the exhaust port.

6. The heat treatment apparatus of claim 5 further comprising:
a vacuum pump in fluid communication with the exhaust port, the vacuum pump operative to continuously evacuate the atmosphere in the process space through the exhaust port.

7. The heat treatment apparatus of claim 6 further comprising:
a gas injector unit coupled with the process space inside the enclosure, the gas injector unit configured to introduce fresh gas into the atmosphere in the process space.

8. The heat treatment apparatus of claim 6 further comprising:
an exhaust pipe connecting the exhaust port with the vacuum pump.

9. The heat treatment apparatus of claim 8 wherein the residual gas analyzer is coupled in fluid communication with the exhaust pipe.

10. The heat treatment apparatus of claim 1 wherein the heating element is embedded in the substrate support.

11. A method for curing a layer of a processable material on a substrate, the method comprising:
baking the layer of material inside a process chamber to generate a gaseous product evolved from the processable material in the layer;
measuring a concentration of the gaseous product inside the process chamber as a function of bake time; and
adjusting a length of the bake time in response to the measured concentration of the gaseous product.

12. The method of claim 11 further comprising:
issuing a warning to a user when the concentration of the gaseous product approaches an allowable limit.

13. The method of claim 11 further comprising:
issuing a warning to a user in conjunction with adjusting the length of the bake time.

14. The method of claim 11 wherein adjusting the length of bake time further comprises:
increasing the length of bake time when the concentration of the gaseous product is greater than an allowable limit.

15. The method of claim 11 wherein adjusting the length of bake time further comprises:
decreasing the length of bake time when the concentration of the gaseous product is lower than an allowable limit.

16. The method of claim 11 wherein measuring a concentration further comprises:
sampling a partial pressure of the gaseous product over a period of time in the process chamber; and
averaging the partial pressures sampled during the period of time to generate the concentration.

17. The method of claim 16 wherein the period of time for sampling is at least about 5 seconds or longer.

18. The method of claim 11 wherein the gaseous product originates from at least one substance in the processable material.

19. The method of claim 18 wherein the at least one substance is selected from a solvent, a polymer, a photo acid generator, a base inhibitor, and combinations thereof.

20. The method of claim 11 further comprising:
exhausting a portion of the gaseous product from the process chamber; and
introducing fresh gas into the process chamber to replace the exhausted gaseous product.

21. The method of claim 11 wherein the processable material comprises at least one organic material selected from a top coat material, an anti-reflection material, a resist, and combinations thereof.
